(19) United States
(12) Patent Application Publication
(10) Pub. No.: US 2021/0359021 A1
(43) Pub. Date: Nov. 18, 2021

(54) CONTROL PANEL AND METHOD FOR FABRICATING SAME

(71) Applicant: WUHAN CHINA STAR OPTOELECTRONICS SEMICONDUCTOR DISPLAY TECHNOLOGY CO., LTD., Wuhan (CN)

(72) Inventors: Simin PENG, Wuhan (CN); Cunjun XIA, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/640,369

(22) PCT Filed: Nov. 20, 2019
(86) PCT No.: PCT/CN2019/119580

§ 371 Date: Feb. 20, 2020

(30) Foreign Application Priority Data
Aug. 16, 2019 (CN) 201910756500.0

(51) Int. Cl. H01L 27/32; H01L 51/52

(52) U.S. Cl. CPC H01L 27/323; H01L 51/0011; H01L 51/5237; H01L 27/3246

(57) ABSTRACT

The present disclosure provides a touch panel and a method for fabricating same, in which patterned touch layers are formed by coating and curing a transparent conductive solution. This can reduce an etching process, thereby preventing an encapsulation layer from being damaged. Furthermore, the formed touch layers can be disposed at any position in a display area without affecting light-emitting effects of an organic light-emitting diode display panel and can greatly improve flexibility of the organic light-emitting diode display panel.

The present application claims priority to Chinese Patent Application No. 201910756500.0, entitled “Display Panel and Display Device”, filed on Aug. 16, 2019 with the China National Intellectual Property Administration, which is incorporated by reference into the present disclosure in its entirety.

### FIELD OF INVENTION

The present invention relates to the technical field of display, and particularly to a control panel and a method for fabricating same.

### BACKGROUND

In a process for fabricating current touch panels (TPs), patterning is generally performed by etching. An etching process is relatively complicated and prone to problems such as incomplete etching and etching liquid/gas residue. On the one hand, formation of a TP on an encapsulation layer by a wet process will increase a risk of encapsulation failures. On the other hand, titanium/aluminum/titanium (Ti/Al/Ti) as a touch conductive material has poor transparency. Therefore, when forming the TP, wiring can be performed only in a non-pixel region. Not only is a location of the wiring limited, but a line width requirement of Ti/Al/Ti is strict. And thus, the process for fabricating the TP has high requirements and difficulties.

Therefore, it is necessary to develop a touch panel to achieve high transparency and high flexibility.

### SUMMARY OF DISCLOSURE

A purpose of the present disclosure is to provide a touch panel and a method for fabricating same, which can solve the above problems in the prior art.

In order to solve the above problems, the present disclosure provides a touch panel and a method for fabricating same.

The present disclosure provides a touch panel comprising: an array layer; a pixel defining layer and an anode layer, which are disposed on the array layer at intervals; an organic light-emitting layer disposed on the anode layer in the opening of the pixel defining layer; an encapsulation layer covering the pixel defining layer and the organic light-emitting layer; a first touch layer disposed on the encapsulation layer and composed of silver nanowires; a first insulating layer disposed on the first touch layer and composed of at least one of silicon nitride and silicon oxide; a second touch layer disposed on the first insulating layer and composed of silver nanowires; and a second insulating layer disposed on the second touch layer and composed of at least one of silicon nitride and silicon oxide.

The present disclosure further provides a touch panel comprising: an array layer; a pixel defining layer and an anode layer, which are disposed on the array layer at intervals; an organic light-emitting layer disposed on the anode layer in the opening of the pixel defining layer; an encapsulation layer covering the pixel defining layer and the organic light-emitting layer; a first touch layer disposed on the encapsulation layer and composed of silver nanowires; and a first insulating layer disposed on the first touch layer.

In an embodiment, the touch panel further comprises: a second touch layer disposed on the first insulating layer and composed of silver nanowires; and a second insulating layer disposed on the second touch layer.

In an embodiment, the second insulating layer is composed of at least one of silicon nitride and silicon oxide.

In an embodiment, the first insulating layer is composed of at least one of silicon nitride and silicon oxide.

In an embodiment, the encapsulation layer comprises a first inorganic layer, an organic layer, and a second inorganic layer which are sequentially stacked in a direction away from the array layer. The first inorganic layer and the second inorganic layer are composed of at least one of silicon nitride, silicon carbonitride, and silicon oxide. The organic layer is composed of at least one of propylene, hexamethyldisiloxane, polyacrylates, polycarbonates, and polystyrene.

The present disclosure further provides a method for fabricating a touch panel. The method comprises: forming a pixel defining layer, an anode layer, and an organic light-emitting layer on an array layer; forming an encapsulation layer on the pixel defining layer and the organic light-emitting layer; and sequentially forming a first touch layer and a first insulating layer on the encapsulation layer.

In an embodiment, the method further comprises sequentially forming a second touch layer and a second insulating layer on the first insulating layer after the sequentially forming a first touch layer and a first insulating layer on the encapsulation layer.

In an embodiment, the organic light-emitting layer is deposited on the anode layer by a vapor deposition process and a mask plate.

In an embodiment, the encapsulation layer comprises a first inorganic layer, an organic layer, and a second inorganic layer which are sequentially stacked in a direction away from the array layer. The first inorganic layer is formed on the organic light-emitting layer by chemical vapor deposition. The organic layer is formed on the first inorganic layer by inkjet printing or chemical vapor deposition. The second inorganic layer is formed on the organic layer by chemical vapor deposition.

In an embodiment, the first touch layer is formed by coating a transparent conductive solution on the encapsulation layer by inkjet printing, evaporating a solvent in the transparent conductive solution, and curing the transparent conductive solution with ultraviolet. The second touch layer is formed by coating the transparent conductive solution on the first insulating layer by inkjet printing, evaporating the solvent in the transparent conductive solution, and curing the transparent conductive solution with ultraviolet.

In an embodiment, the transparent conductive solution comprises silver nanowires.

Compared with the prior art, in the present invention, a transparent conductive solution composed of silver nanowires is coated on an encapsulation layer by an inkjet printing process to form a patterned touch layer, thereby simplifying a fabricating process. Since there is no etching process, the encapsulation layer will not be damaged. On the one hand, due to high transparency of the silver nanowires, the formed touch layer can be disposed at any position in a light-emitting region without affecting light-emitting effects of an organic light-emitting diode display panel. On the other hand, because the silver nanowires have excellent flexibility, flexibility of the organic light-emitting diode display panel can be greatly improved. Therefore, a display panel that can be bent or even curled can be formed.

### BRIEF DESCRIPTION OF DRAWINGS

FIG. 1 is a schematic structural diagram of a touch panel according to an embodiment of the present invention.

FIG. 2 is a schematic structural diagram of an encapsulation layer according to an embodiment of the present invention.

FIG. 3 is a top view of a circuit structure of a touch panel according to an embodiment of the present invention.

FIG. 4 is a schematic flowchart of a method for fabricating a touch panel according to an embodiment of the present invention.

FIG. 5 to FIG. 7 are schematic diagrams of a method for fabricating a touch panel according to an embodiment of the present invention.

### DETAILED DESCRIPTION

Technical solutions in embodiments of the present disclosure will be clearly and completely described below in conjunction with accompanying drawings in the embodiments of the present disclosure. It is apparent that the described embodiments are merely a part of the embodiments of the present disclosure and not all embodiments. All other embodiments obtained by those skilled in the art based on the embodiments of the present disclosure without creative labor are within claimed scope of the present disclosure.

Terms “first”, “second”, “third”, and the like (if present) in the specification, the claims, and the accompanying drawings of the present application are used to distinguish similar objects, rather than used to indicate a particular order or sequence. It should be understood that the objects so described are interchangeable under appropriate circumstances. Furthermore, terms “comprise”, “have”, and any other variation thereof are intended to cover a non-exclusive inclusion.

In the present disclosure, the accompanying drawings discussed hereinafter and the various embodiments used to describe principles of the present disclosure are merely for illustration and should not be construed as limiting the claimed scope of the present application. Those skilled in the art will understand that the principles of the present disclosure may be implemented in any suitably arranged system. Exemplary embodiments will be described in detail, and examples of the embodiments are shown in the accompanying drawings. In addition, a terminal according to the exemplary embodiments will be described in detail with reference to the accompanying drawings in which same reference numerals represent same components.

The terms used herein are only used to describe specific embodiments and are not intended to limit concepts of the present application. Singular form is intended to include plural form as well unless the context clearly indicates otherwise. It should be understood that terms “comprises”, “have”, and “comprising” used herein are intended to indicate presences of features, numbers, steps, operations, or a combination thereof disclosed in the present disclosure, but are not intended to exclude possibility that one or more other features, numbers, steps, operations, or a combination thereof may be present or may be added. Same reference numerals in the accompanying drawings refer to same components.

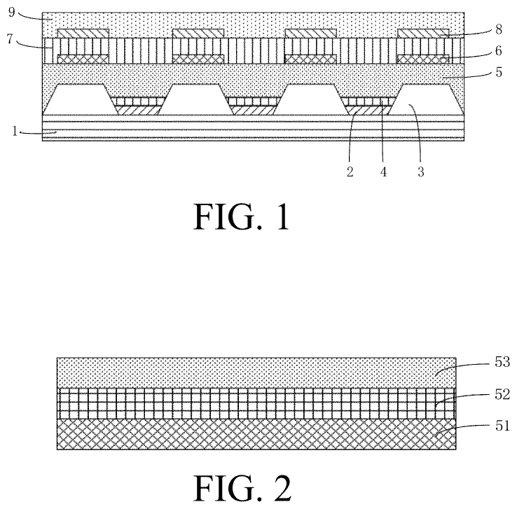

As shown in FIG. 1, the present disclosure provides a touch panel comprising an array layer 1, an anode layer 2, a pixel defining layer 3, an organic light-emitting layer 4, an encapsulation layer 5, a first touch layer 6, a first insulating layer 7, a second touch layer 8, and a second insulating layer 9.

The anode layer 2 and the pixel defining layer 3 are disposed on the array layer 1 at intervals. Thickness of the pixel defining layer 3 is greater than thickness of the anode layer 2 to form openings. The anode layer 2 is composed of, but is not limited to, indium tin oxide, indium zinc oxide, copper, platinum, and silicon.

The organic light-emitting layer 4 is disposed on the anode layer 2 in the opening of the pixel defining layer 3 to reduce interference among different light-emitting points and avoid affecting light-emitting effects.

The encapsulation layer 5 covers the pixel defining layer 3 and the organic light-emitting layer 4. The encapsulation layer 5 may be a single-layer structure or multi-layer structure of an inorganic film layer, an organic film layer, or a combination thereof. As shown in FIG. 2, the encapsulation layer 5 comprises a first inorganic layer 51, an organic layer 52, and a second inorganic layer 53 that are sequentially stacked in a direction away from the array layer 2. The first inorganic layer 51 and the second inorganic layer 53 are composed of at least one of silicon nitride, silicon carbonitride, and silicon oxide. The organic layer 52 is composed of at least one of propylene, hexamethyldisiloxane, polyacrylates, polycarbonates, and polystyrene. The encapsulation layer 5 adopts a stack structure of an organic layer and an inorganic layer to block water and oxygen. A main function of the inorganic layers is to block water and oxygen. A main function of the organic layer is to encapsulate particles and release stress.

The first touch layer 6 is disposed on the encapsulation layer 5 and composed of silver nanowires. A transparent conductive solution composed of silver nanowires can be used to form a conductive layer having relatively high transparency (Tr>91%) and excellent flexibility. The TP layer composed of the silver nanowires can be disposed on any position of a display area, that is, it can be disposed on a light-emitting area or on a non-light-emitting area. Furthermore, it can increase flexibility and light extraction efficiency of an organic light-emitting diode panel.

The first insulating layer 7 is disposed on the first touch layer 6. The first insulating layer 7 is composed of at least one of silicon nitride and silicon oxide and is configured to protect the first touch layer 6.

The second touch layer 8 is disposed on the first insulating layer 7 and composed of silver nanowires. A transparent conductive solution composed of silver nanowires can be used to form a conductive layer having relatively high transparency (Tr>91%) and excellent flexibility. The TP layer composed of the silver nanowires can be disposed on any position of the display area, that is, it can be disposed on the light-emitting area or on the non-light-emitting area. Furthermore, it can increase the flexibility and the light extraction efficiency of the organic light-emitting diode panel.

The second insulating layer 9 is disposed on the second touch layer 8. The second insulating layer 9 is composed of at least one of silicon nitride and silicon oxide and is configured to protect the second touch layer 8. Electrodes of the two touch layers and a finger form a self-capacitance, which has advantages of high accuracy, good performance, and high yield.

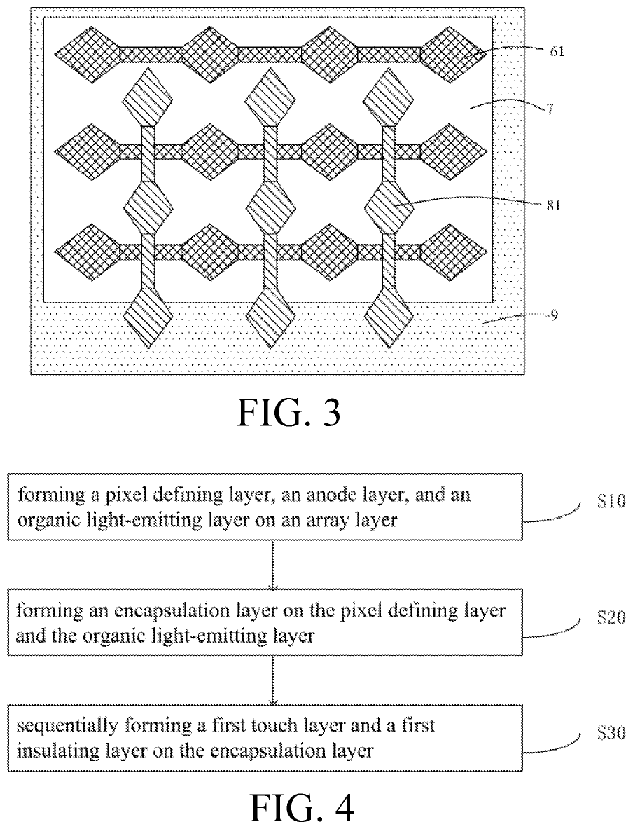

Please refer to FIG. 3, which is a top view of a circuit structure of the touch panel of FIG. 1. The first touch layer 6 comprises sensing electrodes 61. The second touch layer 8 comprises driving electrodes 81. A coupling capacitance is formed between two adjacent electrodes. When a finger touches a screen, the coupling capacitance decreases. A change amount of the coupling capacitance is detected to determine a position touched by the finger.

As shown in FIG. 4, the present disclosure further provides a method for fabricating a touch panel. The method comprises the following steps.

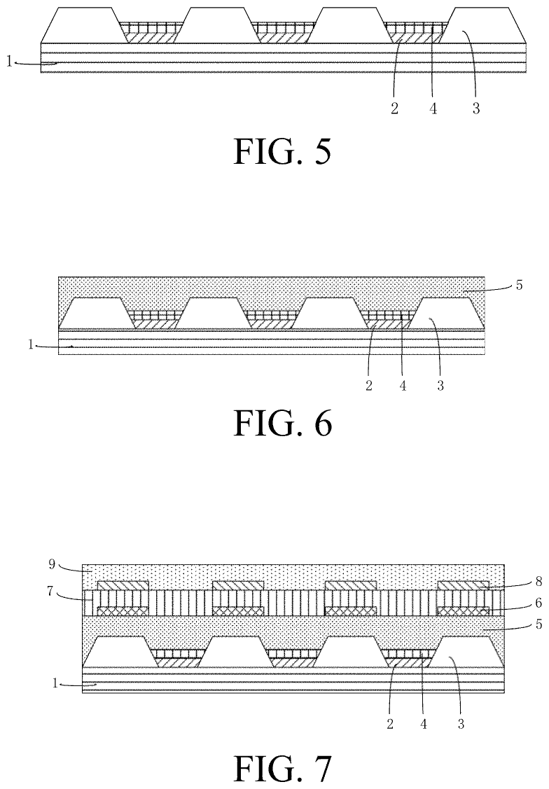

Step S10: forming a pixel defining layer, an anode layer, and an organic light-emitting layer on an array layer. Please refer to FIG. 5. The anode layer 2 is composed of, but is not limited to, indium tin oxide, indium zinc oxide, copper, platinum, and silicon. Thickness of the pixel defining layer 3 is greater than thickness of the anode layer 2 to form openings. The organic light-emitting layer 4 is deposited on the anode layer 2 by a vapor deposition process and a mask plate to reduce interference among different light-emitting points and avoid affecting light-emitting effects.

Step S20: forming an encapsulation layer on the pixel defining layer and the organic light-emitting layer. Please refer to FIG. 6, the encapsulation layer 5 comprises a first inorganic layer 51, an organic layer 52, and a second inorganic layer 53 which are sequentially stacked in a direction away from the array layer 1. The first inorganic layer 51 is formed on the organic light-emitting layer 4 by chemical vapor deposition. The organic layer 52 is formed on the first inorganic layer 51 by inkjet printing or chemical vapor deposition. The second inorganic layer 53 is formed on the organic layer 52 by chemical vapor deposition.

The encapsulation layer 5 adopts a stack structure of an organic layer and an inorganic layer to block water and oxygen. A main function of the inorganic layers is to block water and oxygen. A main function of the organic layer is to encapsulate particles and release stress.

Step S30: sequentially forming a first touch layer and a first insulating layer on the encapsulation layer.

In an embodiment, Step S30 is sequentially forming a first touch layer, a first insulating layer, a second touch layer, a second insulating layer on the encapsulation layer. Please refer to FIG. 7. The first touch layer 6 is formed by coating a transparent conductive solution on the encapsulation layer 5 by inkjet printing, evaporating a solvent in the transparent conductive solution, and curing the transparent conductive solution with ultraviolet. The second touch layer 8 is formed by coating the transparent conductive solution on the first insulating layer 7 by inkjet printing, evaporating the solvent in the transparent conductive solution, and curing the transparent conductive solution with ultraviolet. The transparent conductive solution is composed of silver nanowires. The patterned touch layers are formed by coating and curing the transparent conductive solution. This can reduce an etching process, thereby preventing the encapsulation layer from being damaged.

A transparent conductive solution composed of silver nanowires can be used to form a conductive layer having relatively high transparency (Tr>91%) and excellent flexibility. The TP layer composed of the silver nanowires can be disposed on any position of a display area, that is, it can be disposed on a light-emitting area or on a non-light-emitting area. Furthermore, it can increase flexibility and light extraction efficiency of an organic light-emitting diode panel.

In an embodiment, the first insulating layer 7 is composed of at least one of silicon nitride and silicon oxide and is configured to protect the first touch layer 6. The second insulating layer 9 is composed of at least one of silicon nitride and silicon oxide and is configured to protect the second touch layer 8.

In the present invention, a transparent conductive solution composed of silver nanowires is coated on an encapsulation layer by an inkjet printing process to form a patterned touch layer, thereby simplifying a fabricating process. Since there is no etching process, the encapsulation layer will not be damaged. On the one hand, due to high transparency of the silver nanowires, the formed touch layer can be disposed at any position in a light-emitting region without affecting light-emitting effect of an organic light-emitting diode display panel. On the other hand, because the silver nanowires have excellent flexibility, flexibility of the organic light-emitting diode display panel can be greatly improved. Therefore, a display panel that can be bent or even curled can be formed.

The touch panel and the method for fabricating the same according to the embodiments of the present invention have been described in detail above. The principle and the embodiments of the present invention are described by specific examples. The description of the above embodiments is only intended to help understand the present invention and its core ideas. For those skilled in the art, according to the idea of the present invention, the specific embodiments and application scope may be changed. In the above, content of the present specification should not be construed as a limitation to the present invention.

The subject matters of the present invention can be manufactured and used in industry, and thus are industrially applicable.

1. A touch panel comprising:
an array layer;
a pixel defining layer disposed on the array layer and comprising an opening;
an anode layer disposed on the array layer in the opening of the pixel defining layer;
an organic light-emitting layer disposed on the anode layer in the opening of the pixel defining layer;
an encapsulation layer covering the pixel defining layer and the organic light-emitting layer;
a first touch layer disposed on the encapsulation layer and composed of silver nanowires;
a first insulating layer disposed on the first touch layer and composed of at least one of silicon nitride and silicon oxide;
a second touch layer disposed on the first insulating layer and composed of silver nanowires; and
a second insulating layer disposed on the second touch layer and composed of at least one of silicon nitride and silicon oxide.

2. A touch panel, comprising:
an array layer;
a pixel defining layer disposed on the array layer and comprising an opening;
an anode layer disposed on the array layer in the opening of the pixel defining layer;
an organic light-emitting layer disposed on the anode layer in the opening of the pixel defining layer;
an encapsulation layer covering the pixel defining layer and the organic light-emitting layer;
a first touch layer disposed on the encapsulation layer and composed of silver nanowires; and
a first insulating layer disposed on the first touch layer.

3. The touch panel according to claim 2, further comprising:
a second touch layer disposed on the first insulating layer and composed of silver nanowires; and
a second insulating layer disposed on the second touch layer.

4. The touch panel according to claim 3, wherein the second insulating layer is composed of at least one of silicon nitride and silicon oxide.

5. The touch panel according to claim 3, wherein the first insulating layer is composed of at least one of silicon nitride and silicon oxide.

6. The touch panel according to claim 2, wherein the encapsulation layer comprises a first inorganic layer, an organic layer, and a second inorganic layer which are sequentially stacked in a direction away from the array layer, the first inorganic layer and the second inorganic layer are composed of at least one of silicon nitride, silicon carbonitride, and silicon oxide, and the organic layer is composed of at least one of propylene, hexamethyldisiloxane, polyacrylates, polycarbonates, and polystyrene.

7. A method for fabricating a touch panel, comprising:
forming a pixel defining layer on an array layer, wherein the pixel defining layer comprises an opening;
sequentially forming an anode layer and an organic light-emitting layer on an array layer in the opening;
forming an encapsulation layer on the pixel defining layer and the organic light-emitting layer; and
sequentially forming a first touch layer and a first insulating layer on the encapsulation layer.

8. The method according to claim 7, after the sequentially forming a first touch layer and a first insulating layer on the encapsulation layer, further comprising sequentially forming a second touch layer and a second insulating layer on the first insulating layer.

9. The method according to claim 7, wherein the organic light-emitting layer is deposited on the anode layer by a vapor deposition process and a mask plate.

10. The method according to claim 7, wherein the encapsulation layer comprises a first inorganic layer, an organic layer, and a second inorganic layer which are sequentially stacked in a direction away from the array layer, the first inorganic layer is formed on the organic light-emitting layer by chemical vapor deposition, the organic layer is formed on the first inorganic layer by inkjet printing or chemical vapor deposition, and the second inorganic layer is formed on the organic layer by chemical vapor deposition.

11. The method according to claim 8, wherein the first touch layer is formed by coating a transparent conductive solution on the encapsulation layer by inkjet printing, evaporating a solvent in the transparent conductive solution, and curing the transparent conductive solution with ultraviolet, and the second touch layer is formed by coating the transparent conductive solution on the first insulating layer by inkjet printing, evaporating the solvent in the transparent conductive solution, and curing the transparent conductive solution with ultraviolet.

12. The method according to claim 11, wherein the transparent conductive solution comprises silver nanowires.
